(19) United States
(12) Patent Application Publication
(10) Pub. No.: US 2025/0216471 A1
(43) Pub. Date: Jul. 3, 2025

(54) Method and Device for Controlling DCDC Converter, Computer Program Product and Computer-readable Medium

(71) Applicant: Robert Bosch GmbH, Stuttgart (DE)

(72) Inventor: Fanxi Hu, Wuxi (CN)

(21) Appl. No.: 19/001,692

(22) Filed: Dec. 26, 2024

(30) Foreign Application Priority Data
Dec. 29, 2023 (CN) 2023 1186 3034.9

(51) Int. Cl. G01R 31/389; H01M 8/04858; H02M 3/158

(52) U.S. Cl. CPC G01R 31/389; H01M 8/04865; H02M 3/158; H01M 2250/20

(57) ABSTRACT

A control device for a DCDC converter comprises an upper bridge switch for a step-down mode, a lower bridge switch for the step-down mode, and an inductor. The control device is configured to conduct the upper bridge switch for the step-down mode and to disconnect the lower bridge switch for the step-down mode within a first period. The control device is further configured to disconnect the upper bridge switch for the step-down mode and to conduct the lower bridge switch for the step-down mode within a second period, such that a current passing through the inductor within the second period changes from a positive current to a negative current. A zero current period that the inductor current is disconnected is eliminated by changing the inductor current to a negative value, to avoid operations of the DCDC converter in an intermittent current mode.

This application claims priority under 35 U.S.C. § 119 to patent application no. CN 2023 1186 3034.9, filed on Dec. 29, 2023 in China, the disclosure of which is incorporated herein by reference in its entirety.

The disclosure relates to control over a DCDC converter, and more particularly relates to control over the DCDC converter in an application that determines an electrochemical impedance spectroscopy of a fuel cell.

### BACKGROUND

A fuel cell is a chemical device that converts chemical energy that fuel has into electrical energy. The fuel cell uses fuel and oxygen as feedstocks, and emits less harmful gas. As a result, a vehicle powered by the fuel cell is a hot spot for future development. It is important to be capable of accurately estimating the lifespan of an electrical stack in the fuel cell. Due to a proton exchange membrane (PEM) of the electrical stack being susceptible to being damaged by a damp environment, measuring humidity at the PEM is important for predicting the lifespan of the electrical stack. Typically, a dedicated humidity sensor is used for measuring humidity at the PEM, which adds additional costs and system complexity of the fuel cell. It has been proposed to use an electrochemical impedance spectroscopy method instead of the humidity sensor for humidity measurement. In the electrochemical impedance spectroscopy method, a DCDC converter is utilized to apply an AC current to the fuel cell; and by analyzing a frequency domain response of a response voltage of the fuel cell, the internal impedance of the electrical stack is capable of being analyzed, and the internal resistance of the electrical stack at a high frequency range is capable of reflecting the humidity at the PEM.

Typically, the DCDC converter is required to output a large range of DC current in order to provide an AC current required by the electrochemical impedance spectroscopy method. In case that the DCDC converter is required to output a large range of DC current, it is inevitable that the DCDC converter must be capable of operating in two modes, including an intermittent current mode (DCM) and a continuous current mode (CCM). For a higher output current, the inductor current will not drop to 0 within one pulse width modulation (PWM) cycle of the DCDC converter, thereby making the inductor current continuous (CCM) over multiple PWM cycles; and for a lower output current, the inductor current will drop to 0 within one PWM cycle, thereby making the inductor current intermittent (DCM) over multiple PWM cycles. Since system parameters and transfer functions of the DCDC converter need to be set differently for the DCM and the CCM, when the DCDC converter is required to be capable of operating in two modes including the DCM and the CCM, two sets of controllers are required for the DCM and the CCM respectively to ensure the performance of the DCDC converter in both modes. This undeniably increases the cost and complexity of the system; and meanwhile, key parameters of the two sets of controllers need to be calibrated respectively, which also adds additional workflows.

Accordingly, improved control over the DCDC converter is still desirable to enable it to output a large range of current.

### SUMMARY

The disclosure provides improved control over a DCDC converter; by forcing the DCDC converter to transform from the DCM mode to a CCM mode, such that the DCDC converter only requires to operate in the CCM mode, thereby not requiring to arrange two sets of controllers for the DCDC converter for the DCM and the CCM, respectively.

According to one aspect of the disclosure, provided is a control device for a DCDC converter, the DCDC converter including an upper bridge switch for a step-down mode, a lower bridge switch for the step-down mode, and an inductor, the control device being configured to control the upper bridge switch for the step-down mode and the lower bridge switch for the step-down mode, such that: the upper bridge switch for the step-down mode is conducting and the lower bridge switch for the step-down mode is disconnected within a first period; and the upper bridge switch for the step-down mode is disconnected and the lower bridge switch for the step-down mode is conducting within a second period, such that a current passing through the inductor within the second period changes from a positive current to a negative current.

According to another aspect of the disclosure, provided is a DCDC converter system, including a control device for a DCDC converter according to the principles of the disclosure; and a DCDC converter.

According to yet another aspect of the disclosure, provided is a fuel cell system, including a fuel cell, and a DCDC converter system according to the principle of the disclosure, the DCDC converter system being used for applying an AC current to the fuel cell.

According to yet another aspect of the disclosure, provided is a method for controlling a DCDC converter, the DCDC converter including an upper bridge switch for a step-down mode, a lower bridge switch for the step-down mode, and an inductor, the method including: conducting the upper bridge switch for the step-down mode and disconnecting the lower bridge switch for the step-down mode within a first period; and disconnecting the upper bridge switch for the step-down mode and conducting the lower bridge switch for the step-down mode within a second period, such that a current passing through the inductor within the second period changes from a positive current to a negative current.

According to yet another aspect of the disclosure, provided is a method for determining an electrochemical impedance spectroscopy of a fuel cell, including: controlling the DCDC converter to apply an AC current to the fuel cell using a method according to the principle of the disclosure; measuring a response voltage of the fuel cell to the applied AC current; and analyzing frequency response characteristics of the response voltage to determine an electrochemical impedance spectroscopy of the fuel cell.

According to yet another aspect of the disclosure, provided is a computer program product including instructions, the instructions, when run by a processor, causing the processor to perform a method according to the principle of the disclosure.

According to yet another aspect of the disclosure, provided is a computer-readable medium having instructions stored thereon, the instructions, when run by the processor, causing the processor to perform a method according to the principle of the disclosure.

As noted above, for a lower output current, the inductor current will drop to 0 in one PWM cycle, thereby making the inductor current intermittent over multiple PWM cycles (i.e. the DCDC converter is in the DCM). By changing the inductor current from a positive current to a negative current instead of becoming 0 within the second period (in which the upper bridge switch is disconnected and the lower bridge switch is conducting), a time period during which the inductor current is 0 (the presence of the time period makes the inductor current discontinuous, thereby making the DCDC converter in the DCM) can be eliminated. In other words, the inductor current drops to a negative value in one PWM cycle, and then the inductor current begins to raise from the negative value (instead of the 0 value) in the next PWM cycle, such that the inductor current is always in a continuous state over successive PWM cycles, i.e., the DCDC converter is “forced” to be in the CCM. Thus, for the same DCDC converter, regardless of whether a higher DC current is output or a lower DC current is output, it can operate in the CCM only, thereby not requiring to provide two sets of controllers for the CCM and the DCM, respectively. This may reduce the cost and complexity of the system, and meanwhile, the workflows for calibrating key parameters for the two sets of controllers respectively are saved. Moreover, the degradation of performance brought about by transition between the CCM and the DCM can be mitigated by the elimination of the transition between the CCM and the DCM.

Those skilled in the art will recognize other advantages of the disclosure after reading and understanding the following detailed description.

### BRIEF DESCRIPTION OF THE DRAWINGS

FIGS. 1A and 1B show a general circuit diagram of a DCDC converter for a step-down mode in the prior art in two configurations;

FIGS. 2A and 2B each show a diagram of an inductor current of a DCDC converter in the DCM and the CCM;

FIG. 3 shows a schematic view of a DCDC converter system according to the disclosure;

FIG. 4 shows a diagram of an inductor current of a DCDC converter system according to the disclosure;

FIG. 5 shows a circuit diagram of a 4-switch step-up and step-down type DCDC converter;

FIG. 6 shows a schematic view of a fuel cell system according to the disclosure;

FIG. 7 shows a flow chart of a method for controlling a DCDC converter according to one example of the disclosure; and

FIG. 8 shows a flow chart of a method for determining an electrochemical impedance spectroscopy of a fuel cell according to one example of the disclosure.

### DETAILED DESCRIPTION

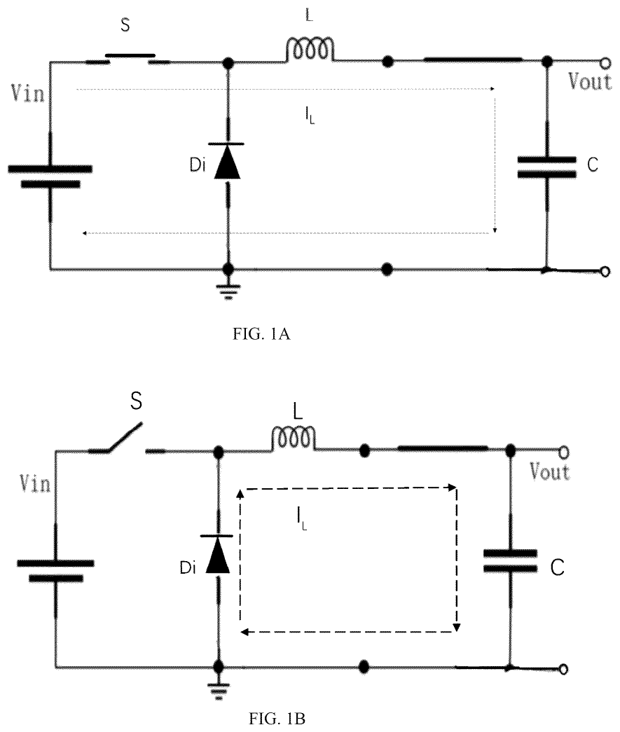

FIGS. 1A and 1B show a general circuit diagram of a DCDC converter for a step-down mode in the prior art. It includes an input voltage source Vᵢₙ, an upper bridge switch S, a lower bridge diode Di, an inductor L, and a capacitor C.

In FIG. 1A, the upper bridge switch S is conducting in the first period T₁ of the PWM cycle, at the time, a voltage source Vᵢₙ charges the inductor L, and a current I_{L} passing through the inductor is gradually raised.

In FIG. 1B, the upper bridge switch S is disconnected in the second period T₂ of the PWM cycle, at the time, a voltage stored by the inductor L is released, which is equivalent to a new power source which supplies power to a load, and the current forms a new loop through the lower bridge diode Di; and the voltage of the inductor L decreases within a short time, and the current I_{L} passing through the inductor gradually decreases. In case that an output current of the DCDC converter is smaller, the current I_{L} passing through the inductor may drop to 0. Since diodes have the property of one-way conduction, after the current I_{L} drops to 0, it will remain at 0 without changing the direction to be a negative value, and a third period T₃ in which the current I_{L} remains 0 is introduced in the PWM cycle.

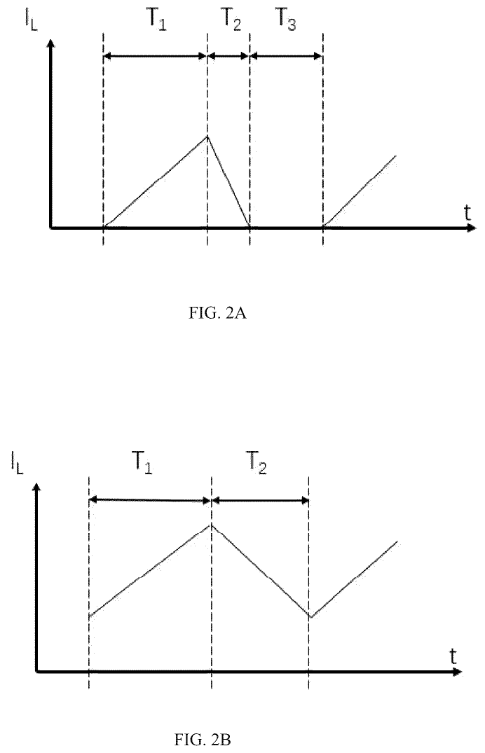

FIG. 2A shows a diagram of the inductor current under the DCM mode, with the horizontal axis as time t and the vertical axis as amplitudes of the inductor current I_{L}. As noted above, in the first period T₁, the upper bridge switch S is conducting, a voltage source Vᵢₙ charges the inductor L, and the current passing through the inductor I_{L} is raised gradually. In the second period T₂, the upper bridge switch S is disconnected, the voltage stored by the inductor L is released, and the current I_{L} passing through the inductor gradually drops to 0. In the third period T3, the current I_{L} remains 0 until the next cycle begins, the upper bridge switch S is conducting again, and the current I_{L} is raised again. As can be seen from FIG. 2A, the current I_{L} passing through the inductor is intermittent over the continuous PWM cycle, which is interrupted by the third period T3. At the time, the DCDC converter is in the DCM mode.

FIG. 2B shows a diagram of the inductor current in the CCM mode, with the horizontal axis as time t and the vertical axis as amplitudes of the inductor current I_{L} similarly. In case that the output current of the DCDC converter is larger, the current I_{L} passing through the inductor does not drop to 0 in the whole PWM cycle. As a result, the second period T₂ can be immediately next to the next PWM cycle, in the next PWM cycle, the inductor current is raised from a non-0 value, thereby forming a continuous current over the continuous PWM cycle. At the time, the DCDC converter is in the CCM mode.

For the DCM and the CCM, the inductor current has different responses.

In the DCM mode, the average inductor current passing may be expressed as:

$${I}_{Average - DCM} = \frac{1}{2} DT \frac{{U}_{i} - {U}_{0}}{L} \qquad ( 1 )$$

In the CCM mode, the average inductor current passing may be expressed as:

$${I}_{Average - CCM} = \frac{1}{2} {D}^{2} T \frac{{U}_{i} ( {U}_{i} - {U}_{0} )}{{U}_{0} L} \qquad ( 2 )$$

Among them, D is the duty cycle, T is the time of the PWM cycle, uᵢ is the input voltage, U₀ is the output voltage, and L is the inductance.

The DCDC converter is a DC-DC converter that outputs the DC current just as its name implies. When applied to an electrochemical impedance spectroscopy method, it is required to provide an AC current to the fuel cell. Thus, there is a need to superimpose alternating control signals to the DC current output by DCDC to provide the AC current. As in equations (1) and (2) above, the AC current may be provided by controlling a change in duty cycle D. Because the inductor current for the DCM and the CCM have different responses, different controller designs and parameters are needed to provide the AC current. Thus, to enable the same DCDC converter to operate both in DCM and in CCM to provide a large range of output current, two different sets of controllers are needed and parameters need to be calibrated respectively for both modes. This increases the cost and complexity of the system and adds a workflow for calibrating critical parameters. Moreover, when the output DC current value is gradually raised to require switching from the DCM to the CCM, an early switch to the CCM is required in order to ensure the stability of the system and ensure the security of the system. For example, where the DCM is suitable for the output current of 0-50 A and the CCM is suitable for the output current of greater than 50 A, the system needs to be switched to the CCM in advance when the output current is gradually raised to about 40 A, and thus the CCM will have to be adopted for a transitional region of 40-50 A, although it is more suitable for the DCM. This degrades performance within the transitional region because the system must be switched in advance to the CCM that would not otherwise be suitable for the transitional region.

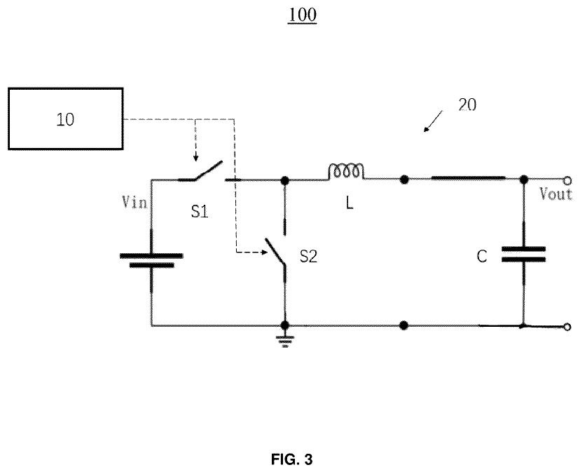

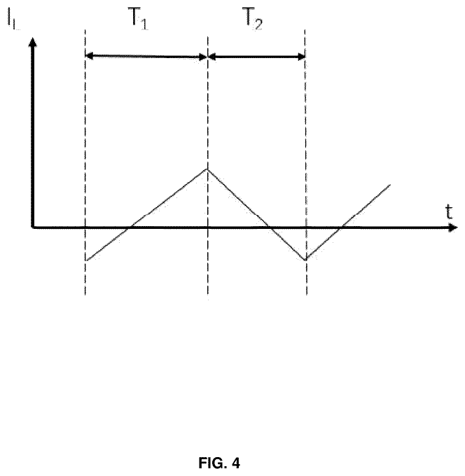

FIG. 3 is a schematic diagram of a DCDC converter system 100 according to the disclosure, the DCDC converter system including a control device 10 for the DCDC converter according to the disclosure and the DCDC converter 20.

The DCDC converter 20 includes an input voltage source Vᵢₙ, an upper bridge switch S1 for a step-down mode, a lower bridge switch S2 for the step-down mode, an inductor L, and a capacitor C.

The control device 10 is used for providing control signals to the DCDC converter 20, in particular to the upper bridge switch S1 and the lower bridge switch S2 of the DCDC controller 20 to control conduction and disconnection of the upper bridge switch S1 and the lower bridge switch S2, respectively.

Specifically, in the step-down mode, in the first period T₁ of the current PWM cycle, the control device 10 is configured to conduct the upper bridge switch S1 and disconnect the lower bridge switch S2 by providing the control signals, at the time, the voltage source Vᵢₙ charges the inductor L, and the inductor current I_{L} is gradually raised; and in the second period T₂ of the PWM cycle, the control device 10 is configured to disconnect the upper bridge switch S1 and conduct the lower bridge switch S2 by providing the control signals, at the time, the voltage stored in the inductor L is released, and the current I_{L} passing through the inductor is gradually reduced.

If the output current is large enough to not reduce the inductor current I_{L} to 0 at the start of the first period T₁ of the next PWM cycle, during the next PWM cycle, the inductor current I_{L} increases from a certain positive value, at the time, the system itself is in the CCM mode, and the diagram of the inductor current under this case is as shown in FIG. 2B.

FIG. 4 shows a diagram of the inductor current of the DCDC converter system 100 according to the disclosure in case that the output current is small, with the transverse axis of time t and the longitudinal axis as magnitudes of the inductor current I_{L}. At the time, due to the fact that the output current is small, the inductor current I_{L} has dropped from a positive value to 0 and continuously dropped to a negative value at the start of the first period T₁ of the next PWM cycle. Thus, in the next PWM cycle, the inductor current I_{L} increases from a certain negative value, at the time, the inductor current I_{L} does not have a broken 0 value between two consecutive PWMs, thereby enabling the system to be in the CCM mode.

This is achieved by: even though the inductor current I_{L} has dropped to 0 in the second period T₂ of the current PWM cycle, the control device 10 insists on keeping the upper bridge switch S1 disconnected and the lower bridge switch S2 conducting, thereby forcing the inductor current I_{L} to change from a positive value to a negative value. In general, the inductor current I_{L} is not allowed to change from a positive value to a negative value. For example, typically, diodes rather than switches are used in a lower bridge. When the inductor current I_{L} drops to 0, the inductor current I_{L} is automatically truncated without becoming a negative value due to one-way conduction of the diodes. Thus, in the disclosure, the switch S2 is used in the lower bridge to replace a diode to achieve dual-way conduction of the switch S2, thereby ensuring that the inductor current I_{L} is capable of changing from a positive current to a negative current. Examples of switches that can achieve dual-way conduction include, but are not limited to, an insulated gate bipolar transistor (IGBT), a metal-oxide semiconductor field-effect transistor (MOSFET), and a triode. The upper bridge switch S1 of the DCDC converter system 100 can also use an IGBT, an MOSFET, or a triode.

Even if a switch is used instead of a diode in the lower bridge, the inductor current I_{L} is typically not allowed to change from a positive value to a negative value. For example, in a typical case, when the current I_{L} of the inductor drops to 0, the lower bridge switch will be disconnected to avoid the inductor current I_{L} from changing from a positive value to a negative value. This is because dropping the inductor current to a negative value will increase a difference between a peak and a valley of the current, and such increased difference may cause the increase of the system loss and increase the heat generated by devices such as capacitors and switches. Since the negative current itself does not supply power to the load, in conventional recognition, having the inductor current I_{L} change from a positive value to a negative value will only have negative effects.

The inventors of the disclosure recognize that even if allowing the inductor current I_{L} to change from a positive value to a negative value may cause problems such as the increased loss and generated heat, etc., it can also avoid switching between the DCM and the CCM when considering a large range of output currents, thereby bringing multiple positive effects. As noted above, this can eliminate the need for two sets of controllers, thereby reducing the cost and complexity of the system; the workflow for calibrating the key parameters of the two sets of controllers respectively can be saved; and the transition between the CCM and the DCM may also be eliminated, thereby mitigating the degradation of performance brought about by such transition.

In one example, in order to provide a greater range of output current, the DCDC converter 20 may also include a switch for the step-up mode. That is, the DCDC converter 20 is a step-up and step-down type converter that can perform both step-up and step-down, thereby further expanding the range of output current.

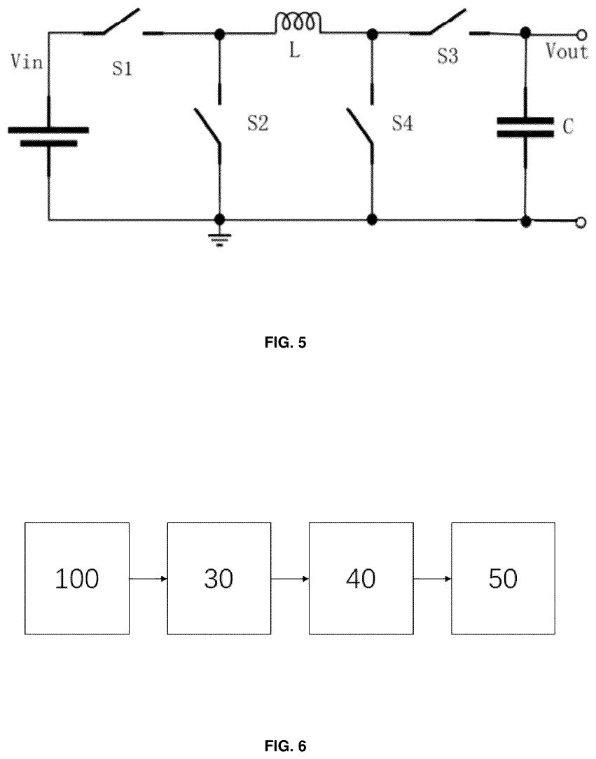

For example, the DCDC converter 20 may also include an upper bridge diode for the step-up mode and a lower bridge switch for the step-up mode. The upper bridge diode for the step-up mode can also be replaced by the switch, in which case the DCDC converter 20 is a 4-switch step-up and step-down type DCDC converter, and FIG. 5 shows a circuit diagram of the 4-switch step-up and step-down type DCDC converter, including the upper bridge switch S1 for the step-down mode, the lower bridge switch S2 for the step-down mode, the upper bridge switch S3 for the step-up mode, and the lower bridge switch S4 for the step-up mode. The switches S1, S2, S3, and S4 may be any of the IGBT, the MOSFET, and the triode.

In the step-down mode, the switch S3 is always conducting, and the switch S4 is always disconnected. Control over switches S1 and S2 is consistent with the previously described examples, i.e., in the first period T₁ of the PWM cycle, the control device 10 is configured to conduct the upper bridge switch S1 and disconnect the lower bridge switch S2; and in the second period T₂ of the PWM cycle, the control device 10 is configured to cause the upper bridge switch S1 to be disconnected and the lower bridge switch S2 to be conducting.

In the step-up mode, the switch S1 is always conducting, and the switch S2 is always disconnected. Control over the switches S3 and S4 is as follows: in the first period T₁ of the PWM cycle, the control device 10 is configured to disconnect the upper bridge switch S3 and conduct the lower bridge switch S4, and at the time, the voltage source Vᵢₙ charges the inductor L; and in the second period T₂ of the PWM cycle, the control device 10 is configured to conduct the upper bridge switch S3 and disconnect the lower bridge switch S4, and the inductor L discharge power to the load.

The DCDC converter system 100 according to various examples of the disclosure described above is particularly suitable for measuring the humidity of a proton exchange membrane of an electrical stack in a fuel cell using the electrochemical impedance spectroscopy method. In practical applications where the humidity of the proton exchange membrane is measured using the electrochemical impedance spectroscopy method, the DCDC converter is typically required to output a wide range of current. The inventors of the present application recognize that in order to accurately measure the humidity of the proton exchange membrane, at least the DCDC converter is required to have the ability to output the DC current ranging from 0-600 A. In general, this necessarily requires the DCDC converter therein to be capable of operating both in the DCM and the CCM, thereby inevitably causing the problems described above due to switching between the DCM and the CCM. Applications of the DCDC converter system 100 according to various examples of the disclosure to measure the humidity of the proton exchange membrane may avoid switching between the DCM and the CCM, thereby avoiding the occurrence of these problems.

Accordingly, the disclosure also provides a fuel cell system. FIG. 6 shows a schematic view of the fuel cell system 600 according to the disclosure. The fuel cell system 600 includes a fuel cell 30 and a DCDC converter system 100 according to various examples of the disclosure. The DCDC converter system 100 is used for applying an AC current to the fuel cell. As documented above, an AC current is provided by superimposing alternating control signals to the DC current output by the DCDC converter system 100.

In one example, the fuel cell system 600 further includes a measurement unit 40 and a determination unit 50. The measurement unit 40 is used for measuring a response voltage of the fuel cell 30 to the applied AC current, and the determination unit 50 is used for analyzing frequency response characteristics of the response voltage to determine an electrochemical impedance spectroscopy of the fuel cell 30. The electrochemical impedance spectroscopy of the fuel cell typically consists of one high frequency region and one low frequency region. The high frequency zone primarily reflects the contribution of electrolyte resistance and electrode polarization to the electrochemical impedance, so the electrochemical impedance of the high frequency zone is capable of reflecting the humidity of the proton exchange membrane.

Those skilled in the art may understand that the measurement unit 40 may represent a hardware module, for example, the measurement unit 40 may be a hardware circuit for collecting electrical signals; or the measurement unit 40 may represent a software module, for example, the measurement unit 40 may be a vehicle-mounted application of a vehicle carrying the fuel cell system 600 that may process the collected electrical signals to calculate the response voltage; or the measurement unit 40 may be a combination of the hardware module and the software module. Likewise, the determination unit 50 may represent a hardware module, for example, the determination unit 50 may be a processor of any computing device, such as a vehicle-mounted processor; or the determination unit 50 may represent a software module, for example, the determination unit 50 may be a vehicle-mounted application of a vehicle carrying the fuel cell system 600 that may cause the processor to analyze the response voltage to determine the electrochemical impedance spectroscopy; or the determination unit 50 may be a combination of the hardware module and the software module.

Although examples in which the DCDC converter system provided by the disclosure is applied to the determination of the electrochemical impedance spectroscopy are described, those skilled in the art may appreciate that the DCDC converter system provided in the disclosure can be applied to any scene where a large range of DC current needs to be outputted.

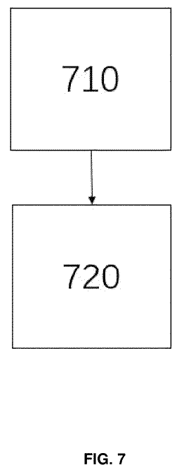

FIG. 7 shows a flow chart of a method 700 for controlling a DCDC converter according to one example of the disclosure, the DCDC converter including an upper bridge switch for a step-down mode, a lower bridge switch for a step-down mode, and an inductor.

In 710, within a first period, the upper bridge switch for the step-down mode is conducting, and the lower bridge switch for the step-down mode is disconnected.

In 720, within the second period, the upper bridge switch for the step-down mode is disconnected, and the lower bridge switch for the step-down mode is conducting, such that a current passing through the inductor within the second period changes from a positive current to a negative current.

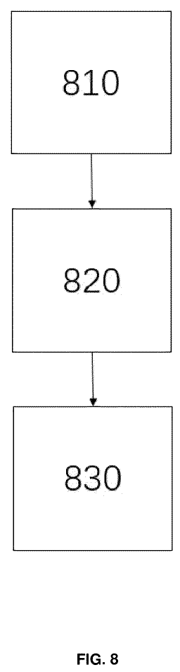

FIG. 8 shows a method 800 for determining an electrochemical impedance spectroscopy of a fuel cell according to one example of the disclosure.

In 810, the method for controlling the DCDC converter provided according to the disclosure is used for controlling the DCDC converter to apply an AC current to the fuel cell.

In 820, a response voltage of the fuel cell to the applied AC current is measured.

In 830, the frequency response characteristics of the response voltage are analyzed to determine the electrochemical impedance spectroscopy of the fuel cell.

It will be understood that the methods according to the disclosure have the same or similar examples as the devices according to the disclosure.

The method shown in FIG. 7 and FIG. 8 can be implemented by the processor executing the corresponding instructions. The instructions may be included in a computer product. For example, the computer product may be downloaded from any appropriate app store. Alternatively, the instructions can be stored on any suitable computer-readable medium.

The methods of the disclosure are described above with reference only to the examples illustrated in FIG. 7 and FIG. 8, understanding that various operations included in the above examples are not limiting and may be removed, combined, varied, split, and/or recombined as desired to increase/modify/delete corresponding functions.

The devices and methods of the disclosure are described above with reference to various examples, examples referred to therein may include particular features, structures or characteristics, but not every example necessarily includes such specific features, structures or characteristics. Further, some examples may have some or all of the features described for other examples or may not have the features described for other examples.

Various features of the different examples or exemplary examples may be variously combined with some of the features contained therein as well as other features excluded, to adapt to a variety of different applications. The accompanying drawings and the foregoing description give exemplary examples of examples. Those skilled in the art will appreciate that one or more of the described elements may be combined into a single functional element. Alternatively, certain elements may be divided into multiple functional elements. Elements from one example may be added to another example. For example, the order of the processes described herein may vary and the processes are not limited to the methods described herein. Further, the operation of any flow diagram needs not be performed in the order shown; nor does it necessarily require all of the operations to be performed. Further, those operations that do not rely on other operations may be performed in parallel with other operations. The scope of the examples is in no way limited by these specific exemplary examples.

Many variations, such as differences in order of operation, product composition and structure, are possible, whether expressly indicated in the specification.

What is claimed is:

1. A control device for a DCDC converter, the DCDC converter comprising an upper bridge switch for a step-down mode, a lower bridge switch for the step-down mode, and an inductor, wherein the control device is configured:
to control the upper bridge switch for the step-down mode and the lower bridge switch for the step-down mode, such that:
the upper bridge switch for the step-down mode is conducting and the lower bridge switch for the step-down mode is disconnected within a first period; and
the upper bridge switch for the step-down mode is disconnected and the lower bridge switch for the step-down mode is conducting within a second period, such that a current passing through the inductor within the second period changes from a positive current to a negative current.

2. The control device according to claim 1, wherein the lower bridge switch for the step-down mode is one of: an insulated gate bipolar transistor, a metal-oxide semiconductor field-effect transistor, and a triode.

3. The control device according to claim 1, wherein the DCDC converter further comprises a switch for a step-up mode.

4. The control device according to claim 3, wherein the DCDC converter is a 4-switch step-up and step-down type DCDC converter.

5. A DCDC converter system, comprising:
the DCDC converter including (i) an upper bridge switch for a step-down mode, (ii) a lower bridge switch for the step-down mode, and (iii) an inductor; and
a control device opeably connected to the DCDC converter, the control device configured to control the upper bridge switch for the step-down mode and the lower bridge switch for the step-down mode, such that:
the upper bridge switch for the step-down mode is conducting and the lower bridge switch for the step-down mode is disconnected within a first period; and
the upper bridge switch for the step-down mode is disconnected and the lower bridge switch for the step-down mode is conducting within a second period, such that a current passing through the inductor within the second period changes from a positive current to a negative current.

6. A fuel cell system, comprising:
a fuel cell; and
the DCDC converter system according to claim 5,
wherein the DCDC converter system is used for applying an AC current to the fuel cell.

7. The fuel cell system according to claim 6, further comprising:
a measurement unit configured to measure a response voltage of the fuel cell to the applied AC current; and
a determination unit configured to analyze frequency response characteristics of the response voltage to determine an electrochemical impedance spectroscopy of the fuel cell.

8. The fuel cell system according to claim 6, wherein the DCDC converter outputs a DC current ranging from 0-600 A.

9. A method for controlling a DCDC converter, the DCDC converter comprising an upper bridge switch for a step-down mode, a lower bridge switch for the step-down mode, and an inductor, the method comprising:
conducting the upper bridge switch for the step-down mode and disconnecting the lower bridge switch for the step-down mode within a first period; and
disconnecting the upper bridge switch for the step-down mode and conducting the lower bridge switch for the step-down mode within a second period, such that a current passing through the inductor within the second period changes from a positive current to a negative current.

10. A method for determining an electrochemical impedance spectroscopy of a fuel cell, comprising:
controlling a DCDC converter to apply an AC current to the fuel cell using the method according to claim 9;
measuring a response voltage of the fuel cell to the applied AC current; and
analyzing frequency response characteristics of the response voltage to determine the electrochemical impedance spectroscopy of the fuel cell.

11. The method according to claim 10, wherein the DCDC converter is capable of outputting a DC current ranging from 0-600 A.

12. The method according to claim 10, wherein a computer program product comprises instructions, which when run by a processor, cause the processor to perform the method.

13. A non-transitory computer-readable medium having the instructions of claim 12 stored thereon.
